(19) United States
(12) Patent Application Publication
(10) Pub. No.: US 2013/0200396 A1
(43) Pub. Date: Aug. 8, 2013

(54) PREVENTION OF LIGHT LEAKAGE IN BACKSIDE ILLUMINATED IMAGING SENSORS

(71) Applicants: Wei Zheng, Los Gatos, CA (US); Vincent Venezia, Los Gatos, CA (US); Hsin-Chih Tai, San Jose, CA (US)

(72) Inventors: Wei Zheng, Los Gatos, CA (US); Vincent Venezia, Los Gatos, CA (US); Hsin-Chih Tai, San Jose, CA (US)

(73) Assignee: OMNIVISION TECHNOLOGIES, INC., Santa Clara, CA (US)

(21) Appl. No.: 13/367,162

(22) Filed: Feb. 6, 2012

(51) Int. Cl. H01L 31/0232

(52) U.S. Cl. 257/80; 438/29; 257/432; 257/E31.127

(57) ABSTRACT

An apparatus includes a semiconductor layer, a dielectric layer, and a light prevention structure. The semiconductor layer has a front surface and a backside surface. The semiconductor layer includes a light sensing element and a periphery circuit region containing a light emitting element and not containing the light sensing element. The dielectric layer contacts at least a portion of the backside surface of the semiconductor layer. At least a portion of the light prevention structure is disposed between the light sensing element and the light emitting element. The light prevention structure is positioned to prevent light emitted by the light emitting element from reaching the light sensing element.

### TECHNICAL FIELD

This disclosure relates generally to imaging sensors, and in particular but not exclusively, relates to backside illuminated (“BSI”) complementary metal-oxide-semiconductor (“CMOS”) imaging sensors.

### BACKGROUND INFORMATION

Many semiconductor imaging sensors today are front side illuminated. That is, these sensors include imaging arrays that are fabricated on the front side of a semiconductor wafer, where incoming light is received at the imaging array from the same front side. Front side illuminated imaging sensors have several drawbacks, for example, a limited fill factor.

BSI imaging sensors are an alternative to front side illuminated imaging sensors. BSI imaging sensors include imaging arrays that are fabricated on the front surface of the semiconductor wafer, but receive incoming light through a back surface of the wafer. At the back surface, a portion of the incoming light enters the device wafer, while another portion of the incoming light is reflected off the back surface. Several approaches may be utilized to increase the portion of the incoming light to enter the device wafer. For example, the back surface may be coated with a backside anti-reflection coating (“BARC”). In areas that are peripheral to the imaging arrays, buffer oxide exists under BARC.

Light that is not external incoming light may be emitted within the silicon substrate of the device wafer by peripheral circuit elements. This internally generated light may enter a dielectric layer including the aforementioned BARC and buffer oxide, travel laterally within it, and then reenter the silicon substrate to reach the imaging arrays therein. Such lateral light may produce undesirable signals, and interfere with the normal operation of BSI imaging sensors.

### BRIEF DESCRIPTION OF THE DRAWINGS

Non-limiting and non-exhaustive embodiments of the invention are described with reference to the following figures, wherein like reference numerals refer to like parts throughout the various views, unless otherwise specified.

FIG. 1 is a cross-sectional view of a BSI imaging sensor illustrating light propagating laterally in a dielectric layer.

FIG. 2 is a cross-sectional view of a BSI imaging sensor illustrating a lateral light blocking scheme including a trench, in accordance with an embodiment of the disclosure.

FIG. 3 is a cross-sectional view of a BSI imaging sensor illustrating a lateral light prevention structure including a void region in a light shield layer, in accordance with an embodiment of the disclosure.

FIG. 4A is a cross-sectional view of a BSI imaging sensor illustrating a lateral light prevention structure, in accordance with an embodiment of the disclosure.

FIG. 4B is a cross-sectional view of a BSI imaging sensor illustrating a lateral light prevention structure, in accordance with an embodiment of the disclosure.

FIG. 5 is a top view of a chip illustrating a BSI imaging sensor with a wall of trenches, in accordance with an embodiment of the disclosure.

FIG. 6 is a flow chart illustrating a method for fabricating a BSI imaging sensor, in accordance with an embodiment of the disclosure.

### DETAILED DESCRIPTION

Embodiments of an apparatus and method for fabricating a BSI imaging sensor that prevents light leakage are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

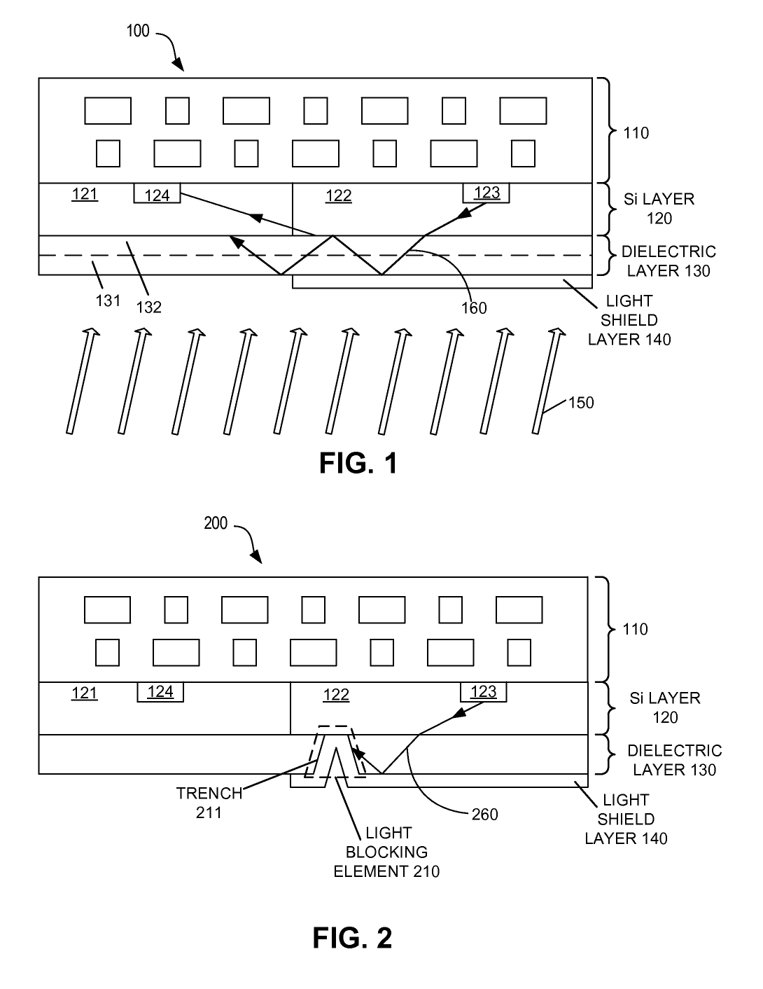

FIG. 1 is a cross-sectional view of a BSI imaging sensor 100 illustrating light propagating laterally in a dielectric layer 130. As shown in FIG. 1, BSI imaging sensor 100 includes a metal stack 110, a semiconductor or silicon (“Si”) layer 120, dielectric layer 130, and a light shield layer 140. Si layer 120 includes a sensor array region 121 containing a number of light sensing element 124 that sense light and a periphery circuit region 122 containing light emitting element 123.

As shown in FIG. 1, dielectric layer 130 includes a backside anti-reflection coating (“BARC”) layer 131 and a buffer layer 132. Buffer layer 132 is deposited on Si layer 120 to provide a buffer between Si layer 120 and BARC layer 131. Buffer oxide layer 132 may be made of materials such as silicon oxide or silicon nitride. BARC layer 131 is deposited on buffer layer 132. BARC layer 131 reduces reflection of incoming light 150, thereby providing a relatively high coupling of incoming light 150 into sensor array region 121. Both BARC layer 131 and buffer layer 132 may act as a light guide. In the following disclosure, these two layers are collectively referred to as dielectric layer 130.

Also shown in FIG. 1 is light shield layer 140, which may cover several areas. First, it covers black level reference pixels (not shown in FIG. 1) disposed in Si layer 120. Black level reference pixels are sensor pixels that do not receive incoming light 150, and provide black level reference for BSI imaging sensor 100. Black level reference pixels may be disposed in periphery circuit region 122. Second, light shield layer 140 may cover periphery circuit region 122. By covering periphery circuit region 122, light shield layer 140 reduces or prevents incoming light 150 from interfering with circuit operations.

Certain elements, such as light emitting element 123 within periphery circuit region 122 may emit light. Light emitting element 123 may emit light by various mechanisms, for example, through electroluminescence of biased p-n junctions, and produce light having wavelength approximately in the infrared (“IR”) or near-IR (“NIR”) spectrum. For example, light emitting element 123 may be a MOS tunnel diode emitting light that includes a wavelength near 1.1 μm. In one embodiment, light emitting element 123 includes a forward biased diode with ion implant induced dislocations, emitting light that includes a wavelength near 1.5 μm.

The light produced by light emitting element 123 may travel laterally to reach sensor array region 121, thereby producing undesirable signals. Dielectric layer 130 may be a conduit through which light travels from light emitting element 123 to light sensing element 124. Several factors are thought to contribute to this phenomenon.

First, IR and NIR light have wavelengths that are close to Si band gap, thus permitting the light to travel relatively long distance in medium such as Si, SiO₂ and SiNₓ (silicon nitride). Light path 160 may be representative of IR or NIR light traveling from light emitting element 123 to light sensing element 124. FIG. 1 illustrates NIR or IR light originating from light emitting element 123, traveling several microns through Si layer 120, entering dielectric layer 130 and traveling laterally along it, and then reentering Si layer 120 to finally reach light sensing element 124.

Second, light may propagate within dielectric layer 130 with relatively little loss of energy due to the phenomenon of total internal reflection. When the refractive index of dielectric layer 130 is greater than the refractive index of Si layer 120, total internal reflection within dielectric layer 130 may occur at the interface between Si layer 120 and dielectric layer 130. The total internal reflection may be further enhanced if the dielectric layer 130 is relatively thin. For example, dielectric layer 130 may be only a fraction of a micron, to a few microns thick.

Third, light shield layer 140 may be composed of metal, which is relatively efficient at reflecting light, thereby confining light (emitted by light emitting element 123) within dielectric layer 130.

Fourth, as the abovementioned light propagates through part of Si layer 120, it may generate charge carriers, such as electrons and holes, which may diffuse into sensor array region 121.

In sum, one or several factors such as the ones mentioned above, as well as their combinations, may cause the IR and NIR light emitted by light emitting element 123 to propagate a relatively long distance in dielectric layer 130, along light path 160, with relatively low loss of energy, to reach light sensing element 124, as shown in FIG. 1. As a result, undesirable signals may interfere with the performance of BSI imaging sensor 100.

Embodiments of light prevention structures or schemes to reduce the amount of internally generated light that reaches light sensing elements of a BSI imaging sensor are disclosed.

FIG. 2 is a cross-sectional view of a BSI imaging sensor 200 illustrating a lateral light blocking structure including a trench, in accordance with an embodiment of the disclosure. BSI imaging sensor 200 includes metal stack 110, Si layer 120, dielectric layer 130, and light shield layer 140. Si layer 120 includes sensor array region 121 containing a number of light sensing element 124 that sense light and periphery circuit region 122 containing light emitting element 123.

Light blocking element 210 is disposed in dielectric layer 130 and positioned to substantially impede light path 260 between light emitting element 123 and light sensing element 124. In the illustrated embodiment, light blocking element 210 includes a trench 211 penetrating through dielectric layer 130 and light shield layer 140 disposed in the trench and on sidewalls of the trench. In one embodiment light, shield layer 140 is optically opaque. In one embodiment, trench 211 only partially penetrates dielectric layer 130. Trench 211 may be located in the portion of dielectric layer 130 that is disposed below periphery circuit region 122, as shown in FIG. 2. Trench 211 may also be located in a portion of dielectric layer 130 that is disposed below sensor array region 121 or in the portion of dielectric layer 130 that covers a region containing black level reference pixel (not shown).

In the illustrated embodiment, light shield layer 140 is shown disposed below periphery circuit region 122. Since light shield layer 140 is disposed below periphery circuit region 122, it covers periphery circuit region 122 from incoming light 150. Light path 260, between light emitting element 123 and light sensing element 124, is substantially impeded by trench 211, as shown in FIG. 2. When trench 211 contains light shield layer 140, the impediment to light path 260 may be increased.

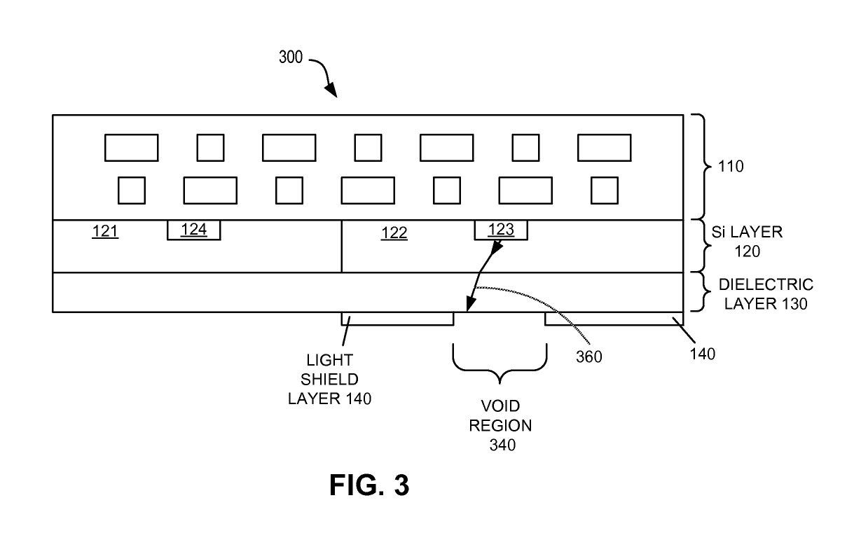

FIG. 3 is a cross-sectional view of a BSI imaging sensor 300 illustrating a lateral light prevention structure including a void region 340 in light shield layer 140, in accordance with an embodiment of the disclosure. BSI imaging sensor 300 includes metal stack 110, Si layer 120, dielectric layer 130, and light shield layer 140. Si layer 120 includes sensor array region 121 containing a number of light sensing element 124 that sense light and periphery circuit region 122 containing light emitting element 123.

Light shield layer 140 substantially covers the backside surface of the portion of Si layer 120 containing light emitting element 123, except in a gap area which is disposed below light emitting element 123, as shown in FIG. 3. This gap in light shield layer 140 is void region 340. The size and position of void region 340 is such that light path 360 (originating from light emitting element 123) encounters void region 340. The absence of light shield layer 140 at void region 340 allows light emitted by light emitting element 123 to escape instead of being reflected by light shield layer 140 back into dielectric layer 130 and traveling laterally through dielectric layer 130 toward light sensing element 124. In one embodiment, light shield layer 140 has more than one gap.

Examples of methods to create BSI imaging sensor 300 are disclosed herein. In one example, light shield layer 140 is deposited upon dielectric layer 130, followed by removing a portion of light shield layer 140 that is disposed below light sensing element 123. In another example, before light shield layer 140 is deposited, a photo-resist layer is formed on an area of dielectric layer 130 which is disposed below light emitting element 123. This may be accomplished by a process such as photo printing. Then, light shield layer 140 is deposited on dielectric layer 130. Finally, the photo-resist layer is removed to create void region 340.

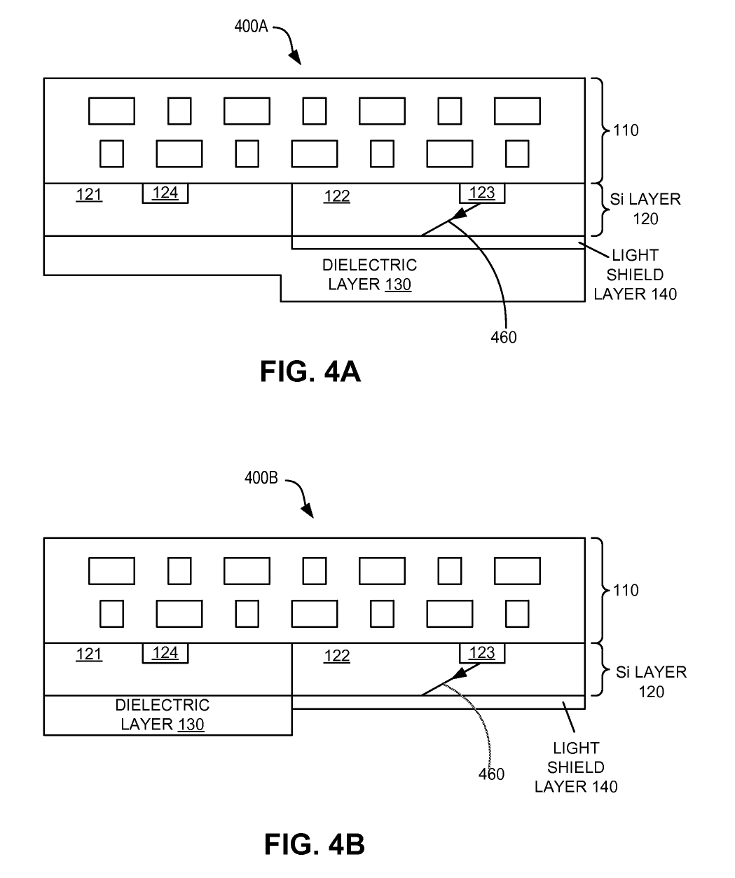

FIG. 4A is a cross-sectional view of a BSI imaging sensor 400A illustrating a lateral light prevention structure, in accordance with an embodiment of the disclosure. BSI imaging sensor 400A includes metal stack 110, Si layer 120, dielectric layer 130, and light shield layer 140. Si layer 120 includes sensor array region 121 containing a number of light sensing element 124 that sense light and periphery circuit region 122 containing light emitting element 123. Light shield layer 140 is disposed on Si layer 120, and covers periphery circuit region 122. Dielectric layer 130 may be disposed on Si layer 120 and cover sensor array region 121 and light shield layer 140.

FIG. 4B is a cross-sectional view of a BSI imaging sensor 400B illustrating a lateral light prevention structure, in accordance with an embodiment of the disclosure. BSI imaging sensor 400B includes metal stack 110, Si layer 120, dielectric layer 130, and light shield layer 140. In FIG. 4B, dielectric layer 130 is disposed on sensor array region 121 of Si layer 120, but does not cover light shield layer 140.

In the illustrated examples of FIGS. 4A and 4B, blocking light paths between light emitting element 123 and light sensing element 124 is accomplished by preventing direct contact between dielectric layer 130 and periphery circuit region 122. As shown in FIGS. 4A and 4B, light path 460 is impeded when light originating from light emitting element 123 reaches light shield layer 140. There, due to the absence of the dielectric layer 130 which acts as a light guide in that area, light propagation towards light sensing element 124 is stopped.

Examples of methods to create BSI imaging sensor 400A and 400B are disclosed herein. In one example, light shield layer 140 is deposited upon periphery circuit region 122 of Si layer 120, followed by depositing dielectric layer 130 upon sensor array region 121 of Si layer 120 and light shield layer 140. In another example, light shield layer 140 is deposited upon periphery circuit region 122 of Si layer 120, followed by depositing dielectric layer 130 upon sensor array region 121, but not on light shield layer 140. These examples of methods may include semiconductor processing methods such as photo printing.

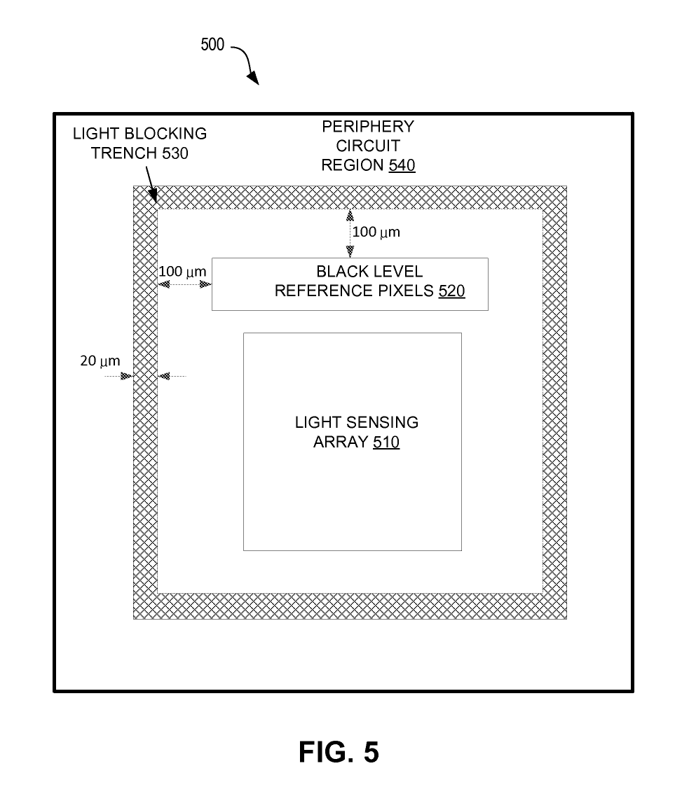

FIG. 5 is a top view of a chip 500 illustrating a BSI imaging sensor with a wall of trenches, in accordance with an embodiment of the disclosure. Light blocking elements (e.g. trenches) may be positioned around a light sensing array and black level reference pixels so that they are isolated from light emitting periphery circuits. By way of example, light blocking elements may include a wall of trenches that encloses a light sensing array and black level reference pixels. Chip 500 includes light sensing array 510 and black level reference pixels 520. Light blocking trench 530 substantially encloses light sensing array 510 and black level reference pixels 520, thus laterally separating them away from periphery circuit region 540. An example of light blocking trench 530 is found in FIG. 2, in which trench 211 is disposed in dielectric layer 130. Light blocking trench 530 may form an enclosure in a rectangular shape, as shown in FIG. 5. Other examples include other geometric shape enclosures (not shown), such as triangle, trapezoid, polygon, circle, oval, etc. In FIG. 5, light blocking trench 530 has a width of about 20 μm when viewed from the top. Other widths are possible (e.g., 10 μm, 100 μm), but are not shown in FIG. 5. Also in FIG. 5, light blocking trench 530 is positioned about 100 μm from black level reference pixels 520, as viewed from the top. Other distances are possible, (e.g., 10 μm, 1000 μm) but are not shown in FIG. 5.

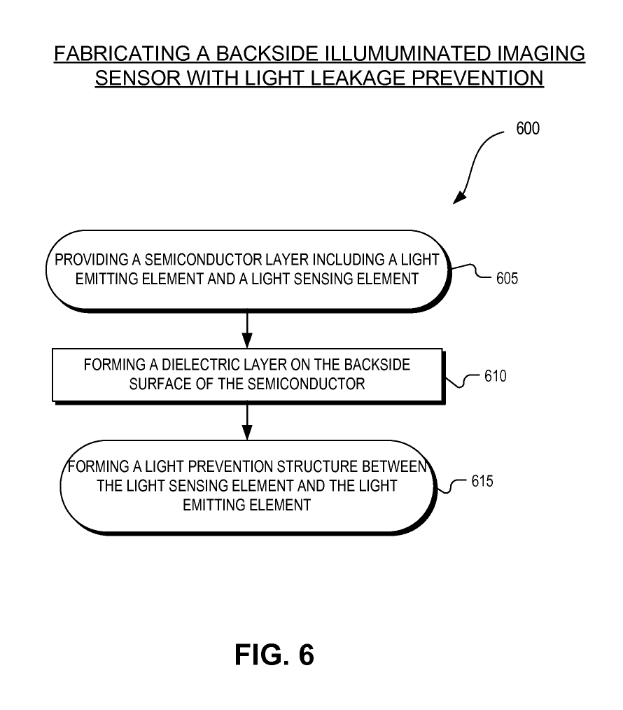

FIG. 6 is a flow chart illustrating a method for fabricating a BSI imaging sensor, in accordance with an embodiment of the disclosure. The order in which some or all of the process blocks appear in process 600 should not be deemed limiting. Rather, one of ordinary skill in the art having the benefit of the present disclosure will understand that some of the process blocks may be executed in a variety of orders not illustrated, or even in parallel.

Process 600 is one example of how to fabricate a BSI imaging sensor. In process block 605, a semiconductor layer having a front surface and a backside surface is provided. The semiconductor layer (e.g. Si layer 120) includes a light sensing element and a periphery circuit region containing a light emitting element. The periphery circuit region may not contain any light sensing elements because light shield layer 140 may prevent a light sensing element from receiving light. In process block 610, a dielectric layer is formed on the backside surface of the semiconductor layer. In process block 615, a light prevention structure is formed. At least a portion of the light prevention structure is disposed between the light sensing element and the light emitting element. A light shield layer may be formed after the dielectric layer is formed.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A backside illuminated sensor device comprising:
a semiconductor layer having a front surface and a backside surface, the semiconductor layer further including a light sensing element and a light emitting element positioned laterally to the light sensing element;
a dielectric layer having a first surface and a second surface wherein the first surface of the dielectric layer is substantially in contact with the backside surface of the semiconductor layer; and
a light blocking element disposed in the dielectric layer between the light sensing element and the light emitting element, the light blocking element positioned to impede a light path between the light emitting element and the light sensing element.

2. The backside illuminated sensor device of claim 1, wherein the light blocking element includes a trench, the trench penetrating the second surface of the dielectric layer.

3. The backside illuminated sensor device of claim 2, wherein the light blocking element further includes a light shield layer disposed in the trench and on sidewalls of the trench, wherein the light shield layer is optically opaque.

4. The backside illuminated sensor device of claim 1, wherein a material of the semiconductor layer permits incoming light to enter the semiconductor layer from the backside surface and reach the light sensing element.

5. The backside illuminated sensor device of claim 1, wherein a first refractive index of the dielectric layer is greater than a second refractive index of the semiconductor layer.

6. The backside illuminated sensor device of claim 1, further comprising a light shield layer substantially in contact with the second surface of the dielectric layer and disposed below a periphery circuit region of the semiconductor layer, the periphery circuit region of the semiconductor layer containing the light emitting element and not containing the light sensing element, wherein the light shield layer substantially prevents light from passing through it.

7. The backside illuminated sensor device of claim 1, wherein the light blocking element substantially surrounds the light sensing element.

8. The backside illuminated sensor device of claim 7, wherein the light blocking element also substantially surrounds black level reference pixels of the backside illuminated sensor device.

9. The backside illuminated sensor device of claim 1, wherein the dielectric layer further includes an anti-reflective coating layer.

10. A backside illuminated sensor device comprising:
a semiconductor layer having a front surface and a backside surface, the semiconductor layer including a light sensing element and a periphery circuit region containing a light emitting element and not containing the light sensing element;
a dielectric layer contacting at least a portion of the backside surface of the semiconductor layer; and
a light prevention structure, wherein at least a portion of the light prevention structure is disposed between the light sensing element and the light emitting element, the light prevention structure positioned to prevent light emitted by the light emitting element from reaching the light sensing element.

11. The backside illuminated sensor device of claim 10, wherein the light prevention structure includes a trench in the dielectric layer.

12. The backside illuminated sensor device of claim 11, wherein the light prevention structure includes a light shield layer disposed in the trench and on sidewalls of the trench.

13. The backside illuminated sensor device of claim 10, wherein the light prevention structure includes:
a light shield layer disposed below the dielectric layer; and
a void region disposed below the light emitting element, wherein the void region is a gap in the light shield layer positioned to allow the light emitted by the light emitting element to escape instead of traveling laterally toward the light sensing element.

14. The backside illuminated sensor device of claim 10, wherein the light sensing element is disposed in a sensor array region of the semiconductor layer and the dielectric layer is disposed below the sensor array region, and wherein the light prevention structure includes a light shield layer contacting the backside surface of the semiconductor layer below the periphery circuit region.

15. The backside illuminated sensor device of claim 14, wherein the dielectric layer contacts the backside surface of the semiconductor layer below the sensor array region, and wherein the dielectric layer is disposed below the light shield layer and below the periphery circuit region.

16. The backside illuminated sensor device of claim 10, wherein a first refractive index of the dielectric layer is greater than a second refractive index of the semiconductor layer.

17. The backside illuminated sensor device of claim 10, wherein the dielectric layer further includes an anti-reflective coating layer.

18. A method of fabricating a backside illuminated sensor device, the method comprising:
providing a semiconductor layer having a front surface and a backside surface, the semiconductor layer including a light sensing element and a periphery circuit region containing a light emitting element and not containing the light sensing element;
forming a dielectric layer onto at least a portion of the backside surface of the semiconductor layer; and
forming a light prevention structure, wherein at least a portion of the light prevention structure is disposed between the light sensing element and the light emitting element, the light prevention structure positioned to prevent light emitted by the light emitting element from reaching the light sensing element.

19. The method of claim 18, wherein the light prevention structure includes a trench in the dielectric layer.

20. The method of claim 19, wherein the light prevention structure includes a light shield layer disposed in the trench and on sidewalls of the trench.
